(19) United States
(12) Patent Application Publication
(10) Pub. No.: US 2026/0009130 A1
(43) Pub. Date: Jan. 8, 2026

(54) HIGH TEMPERATURE PRECURSOR GAS DELIVERY MANIFOLD

(71) Applicant: Applied Materials, Inc., Santa Clara, CA (US)

(72) Inventors: STEVEN MOSBRUCKER, San Jose, CA (US); ANANTHA SUBRAMANI, San Jose, CA (US); SEYYED FAZELI, Santa Clara, CA (US); ARUN KUMAR KOTRAPPA, Davanagere (IN); CHANDRASHEKARA BAGINAGERE, Bengaluru (IN); RAMCHARAN SUNDAR, Chennai (IN); JOHN LEE, Santa Clara, CA (US); TIM LE, Santa Clara, CA (US); AVGERINOS GELATOS, Santa Clara, CA (US); SHIH YAO HSU, Redwood City, CA (US); THOMAS EMPANTE, Santa Clara, CA (US); PRATHAMESH SAHASTRABUDHE, Sunnyvale, CA (US)

(21) Appl. No.: 18/762,529

(22) Filed: Jul. 2, 2024

(51) Int. Cl. C23C 16/455

(52) U.S. Cl. CPC C23C 16/45561; C23C 16/45565; C23C 16/4557

(57) ABSTRACT

Embodiments described herein relate to an apparatus that includes a thermal block with a gas inlet, and a gas line fluidly coupled to the gas inlet of the thermal block. In an embodiment, a base is coupled to the thermal block, where the base includes an embedded channel coupled to a fluid inlet. In an embodiment, an air gap is provided between at least a portion of the thermal block and a portion of the base.

### BACKGROUND

### 1) Field

Embodiments of the present disclosure pertain to the field of three-dimensional (3D) printed gas delivery manifolds for delivering high temperature precursor gases to a chamber.

### 2) Description of Related Art

In many semiconductor manufacturing processes, gasses are flown into a chamber in order to deposit a layer, etch a layer, treat a layer, clean a chamber, and/or the like. Careful control of the temperature of the gas as it enters the chamber is necessary in order to obtain desired processing outcomes. Typically, the gasses flown into the chamber are at a relatively low temperature, such as below 150° C. The relatively low temperatures may be used because the gasses that are flown into the chamber remain in the gas phase even at such low temperatures.

However, gasses with high condensation temperatures may be necessary in order to obtain a desired processing result in certain processing regimes. For example, ZrCl gas may be used as a precursor in a plasma enhanced (PE) deposition of titanium. ZrCl gas needs to be kept above 210° C. in order to prevent the precursor from condensing. The input of the gas delivery manifold may be heated in order to obtain the necessary temperature of the gas through the gas delivery manifold. Unfortunately, the high power necessary to maintain the gas at the desired temperature results in a lot of thermal energy being dissipated into the remainder of the gas delivery manifold.

### SUMMARY

Embodiments described herein relate to an apparatus that includes a thermal block with a gas inlet, and a gas line fluidly coupled to the gas inlet of the thermal block. In an embodiment, a base is coupled to the thermal block, where the base includes an embedded channel coupled to a fluid inlet. In an embodiment, an air gap is provided between at least a portion of the thermal block and a portion of the base.

Embodiments described herein relate to an apparatus that includes a monolithic gas delivery manifold. In an embodiment, the monolithic gas delivery manifold includes a gas line, where a gas input to the gas line is at a surface of a thermal block. The monolithic gas delivery manifold may also include a base, that includes a fluidic channel. In an embodiment, an air gap is provided between at least a portion of the thermal block and a portion of the base. In an embodiment, the apparatus further comprises a remote plasma source (RPS) mount above the base. In an embodiment, the RPS mount is coupled to the base by a plurality of support columns. In an embodiment, a plasma isolation valve is provided between the RPS source mount and the base. In an embodiment, a vertical pipe is fluidically coupled to the gas line. In an embodiment, an interior of a chamber is fluidically coupled to the vertical pipe.

Embodiments described herein relate to an apparatus that includes a chamber and a gas delivery manifold fluidly coupled to the chamber. In an embodiment, the gas delivery manifold includes a gas line that is configured to be heated, and the gas line includes a vertical portion and a horizontal portion. In an embodiment, a remote plasma source (RPS) is coupled to the gas delivery manifold, where the RPS is fluidly coupled to an interior of the chamber by a path that passes through the gas delivery manifold.

### BRIEF DESCRIPTION OF THE DRAWINGS

FIG. 1A is a cross-sectional illustration of a portion of a gas delivery manifold, in accordance with an embodiment.

FIG. 1B is a perspective view illustration of a portion of a gas delivery manifold, in accordance with an embodiment.

FIG. 1C is a cross-sectional illustration of a portion of a gas delivery manifold, in accordance with an embodiment.

FIG. 1D is a cross-sectional illustration of a portion of a gas delivery manifold with an integrated plasma isolation valve, in accordance with an embodiment.

FIG. 2A is a cross-sectional illustration of a gas delivery manifold coupled to a chamber lid and a showerhead, in accordance with an embodiment.

FIG. 2B is a cross-sectional illustration of a gas delivery manifold with a remote plasma source (RPS) mount coupled to a chamber lid and a showerhead, in accordance with an embodiment.

FIG. 3A is a cross-sectional illustration of a portion of a gas delivery manifold with a gas input line and a cooling fluid input line that are coupled to the gas delivery manifold with O-rings, in accordance with an embodiment.

FIG. 3B is a cross-sectional illustration of a portion of a gas delivery manifold with a gas input line and a cooling fluid input line, where the gas input line is brazed or welded to the gas delivery manifold, in accordance with an embodiment.

FIG. 4 is a cross-sectional illustration of a plasma processing tool with a monolithic gas delivery manifold for delivering high temperature precursor gases to a chamber, in accordance with an embodiment.

FIG. 5 is a flow diagram of a process for flowing a high temperature precursor gas into a chamber through a three-dimensional (3D) printed gas delivery manifold, in accordance with an embodiment.

FIG. 6 illustrates a block diagram of an exemplary computer system of a processing tool, in accordance with an embodiment of the present disclosure.

### DETAILED DESCRIPTION

Three-dimensional (3D) printed gas delivery manifolds for delivering high temperature precursor gases to a chamber are disclosed herein, in accordance with various embodiments. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, certain plasma processing recipes require gasses with high condensation temperatures. For example, ZrCl gas may be used as a precursor in a plasma enhanced (PE) deposition of titanium. ZrCl gas needs to be kept above 210° C. in order to prevent the precursor from condensing. The input of the gas delivery manifold may be heated in order to maintain the necessary temperature of the gas through the gas delivery manifold. Unfortunately, the high power necessary to maintain the gas at the desired temperature results in a lot of thermal energy being dissipated into the remainder of the gas delivery manifold. Since the thermal energy rapidly dissipates throughout the entire gas delivery manifold, high power inputs are necessary to maintain the temperature of the gas deliver line at the necessary temperature.

Accordingly, embodiments disclosed herein include a gas delivery manifold that is assembled with a three-dimensional (3D) printing process. The use of a 3D printing process allows for the manufacture of structures within the gas delivery manifold that are otherwise not possible with traditional machining processes. For example, embedded channels for cooling fluids can be provided. The embedded channels may also have paths that are oriented horizontally, vertically, or at any other angle. This allows for unique routing options for the integrated channels in order to control heat transfer. Additionally, thermal choking features that are formed into the gas delivery manifold allow for the thermal energy to be coupled to the gas without also bringing the overall temperature of the outer surfaces of the gas delivery manifold to dangerous temperatures. That is, air gaps can be formed into the gas delivery manifold in order to thermally isolate the gas delivery line from a reminder of the gas delivery manifold. Further, the use of a 3D printing process allows for the formation of a monolithic gas delivery manifold. This avoids the need to join multiple components together. As such, assembly and manufacture of the gas delivery manifold is easier, and the elimination of seams between components eliminates potential leaks where components are joined together. In an embodiment, the gas delivery manifold may be coupled to a 3D printed ceramic shell that surrounds a vertical pipe that feeds the gas into the chamber. The 3D printed ceramic shell is used to separate the gas delivery manifold (which is held at RF ground) from a chamber lid (which is RF hot) in order to prevent plasma from lighting.

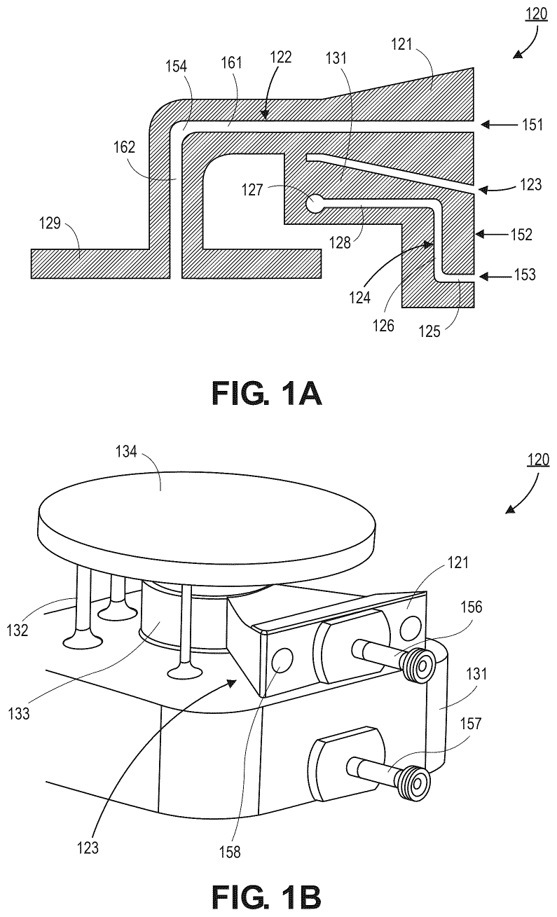

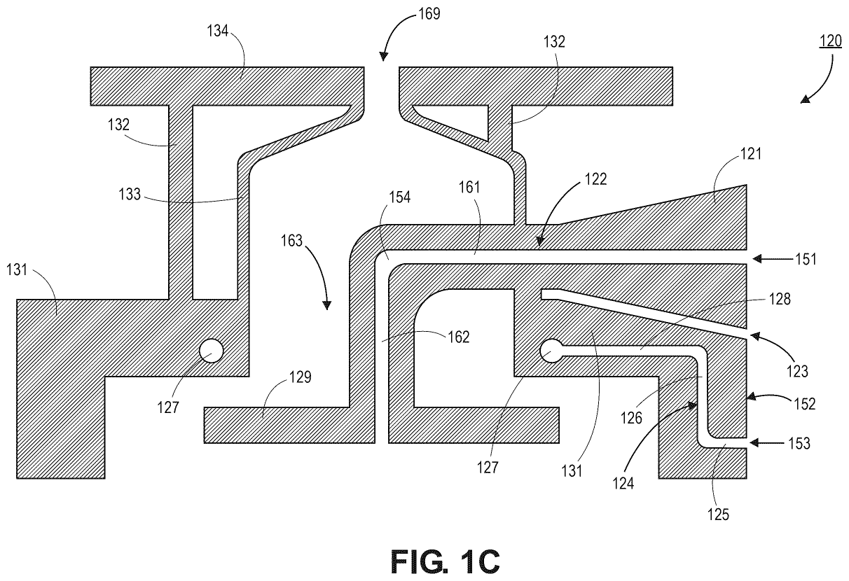

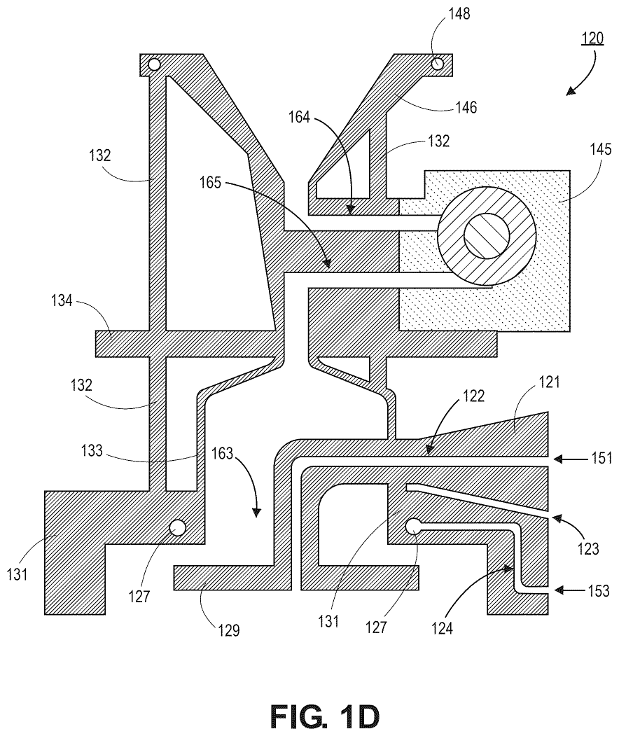

Referring now to FIG. 1A, a cross-sectional illustration of a portion of a gas delivery manifold 120 is shown, in accordance with an embodiment. In an embodiment, the gas delivery manifold 120 may comprise a thermal block 121. The thermal block 121 may be heated by a power input (not shown) that is coupled to the thermal block 121. In an embodiment, the thermal block 121 may include a wide end at an input 151 of the gas line 122, and the thermal block 121 may narrow as the thermal block 121 extends towards a center of the gas delivery manifold 120. In an embodiment, the thermal block 121 may be brought to a high temperature in order to rapidly heat or maintain a temperature of the gas that is being flown into the gas line 122. For example, the thermal block 121 may be brought to a temperature of approximately 200° C. or higher, or to a temperature of approximately 300° C. or higher.

Further, due to the good thermal isolation, the thermal block 121 may only need to be supplied with about 230 W to 250 W of power in order to reach the desired temperature. For example, the thermal block 121 may be thermally isolated from a base 131 of the gas delivery manifold 120 by an air gap 123. In an embodiment, the air gap 123 may be oriented at an angle that is non-orthogonal to a sidewall surface 152 of the base 131. Though, the air gap 123 may be provided at substantially any angle. Further, FIG. 1A illustrates that the air gap 123 may include a bend. For example, a bend in the air gap 123 is shown at the narrow end of the thermal block 121. The ability to form such non-planar air gaps 123 is enabled through the use of the 3D printing process. That is, it would be extremely difficult (if not impossible) to provide such a non-planar air gap 123 between the thermal block 121 and the base 131 using traditional subtractive manufacturing processes.

In an embodiment, the thermal block 121 and the base 131 may be formed as a monolithic structure when a 3D printing process is used. That is, there may not be any seam at an interface between the thermal block 121 and the base 131. The production of a monolithic structure for the gas delivery manifold 120 allows for simpler manufacturing since there are fewer individual components to produce. The reduction in components makes assembly and integration with a processing chamber easier. Additionally, the elimination of interfaces between components eliminates the potential for leaks within the gas delivery manifold 120. Further, 3D printing processes allow for the generation of regions with small thicknesses that are not possible with traditional machining processes. In an embodiment, the monolithic structure of the gas delivery manifold 120 may comprise any thermally conductive material that is compatible with 3D printing processes. For example, the gas delivery manifold 120 may comprise one or more of aluminum, nickel, stainless steel, or the like.

In an embodiment, the gas line 122 may have a first portion 161 and a second portion 162. The first portion 161 may be substantially horizontal and extend from the gas input 151 towards a center of the gas delivery manifold 120. The second portion 162 may be substantially vertical and extend down from the first portion 161 towards a seal plate 129. That is, the gas line 122 may have at least one turn 154. The turn 154 may be approximately ninety degrees in some embodiments. Though, turns of any angle may also be used. The ability to manufacture a gas line 122 that is oriented along different planes is enabled through the use of the 3D printing process.

In an embodiment, one or more fluidic channels 124 may be embedded within the base 131. A fluidic input 153 may be provided along the sidewall surface 152 of the base 131. The fluidic input 153 may be spaced apart from the thermal block 121 in order to minimize thermal energy at the fluidic input 153. Reducing the temperature of the fluidic input 153 allows for a wider range of O-rings (not shown) that can be used to couple the fluidic pipe to the fluidic input 153. In an embodiment, the fluidic input 153 may be spaced further from the thermal block 121 due to the use of the 3D printing process. For example, a fluidic channel 124 that is embedded in the base 131 may comprise a first portion 125, a second portion 126, and a third portion 128. As shown, the first portion 125 and the third portion 128 are substantially horizontal, and the second portion 126 is substantially vertical. A fluidic channel 124 with portions aligned along orthogonal planes and embedded in a monolithic structure is not possible with traditional subtractive machining processes. In an embodiment, the fluidic channel 124 may be fluidically coupled to a plenum 127. The plenum 127 may be an embedded ring-shaped channel. As such, cooling fluid may be flown through an interior of the base 131 in order to improve cooling of the base 131. Such an embedded channel is also not able to be formed with traditional subtractive machining processes.

As can be appreciated, the monolithic gas delivery manifold 120 allows for localized heating along the gas line 122 while preserving the ability to maintain a cool base 131. As such, danger resulting from an extremely hot surface of the gas delivery manifold 120 is avoided. More particularly, the monolithic structure combined with the 3D printing process allows for fluid cooling and thermal chocking features that provide excellent thermal control within the gas delivery manifold 120.

Referring now to FIG. 1B, a perspective view illustration of a portion of a gas delivery manifold 120 is shown, in accordance with an embodiment. In an embodiment, the gas delivery manifold 120 may comprise a base 131. A central column 133 may extend up from the base 131. As will be described in greater detail herein, the central column 133 may be a shell that allows for gas from the gas inlet and species from a plasma to flow through an opening in the base 131 towards a chamber (not shown). In an embodiment, the base 131 may be coupled to a fluid input line 157. In an embodiment, the fluid input line 157 may be a pipe or the like that delivers a cooling fluid from a coolant source (not shown) to fluidic channels and/or plenums within the base 131. In an embodiment, the fluid input line 157 may be coupled to the fluidic input of the base 131 with any suitable coupling mechanism. For example, O-rings or other suitable seals may be provided between the fluid input line 157 and the base 131.

In an embodiment, the thermal block 121 may be coupled to the central column 133. For example, the gas line may pass through the thermal block 121 and enter the central column 133. In an embodiment, a gas input line 156 may be coupled to the thermal block 121. Due to the high temperature of the thermal block 121, sealing options that are compatible with higher temperatures are used. For example, high temperature O-rings (e.g., a metal coated O-ring, etc.) may be provided between the gas input line 156 and the thermal block 121. In other embodiments, a welding or brazing process may be used to couple the gas input line 156 to the thermal block 121. In an embodiment, the thermal block 121 may comprise one or more thermal inputs 158. The thermal inputs 158 may be receptacles for receiving a power cable. For example, the power cable (not shown) may deliver electrical power to the thermal block 121 and heat the thermal block 121 through resistive heating. In other embodiments, the thermal inputs 158 may receive a heating element that is used to heat the thermal block 121 through heat transfer (e.g., conduction).

In an embodiment, a ledge 134 may be provided over the base 131. The ledge 134 may be used to support structures (not shown) that are provided over the base 131. For example, plasma chambers, a remote plasma source (RPS) mount, or the like may be provided over the ledge 134. In an embodiment, the ledge 134 may also be a monolithic portion of the gas delivery manifold. The ledge 134 may be supported through the use of a plurality of support columns 132. The 3D printing process used to form the gas delivery manifold 120 is also able to form the support columns 132. In an embodiment, the columns 132 may be high aspect ratio support columns 132 (e.g., 3:1 or greater, 5:1 or greater, or 10:1 or greater). The high aspect ratio support columns 132 may be impossible to manufacture using traditional bulk subtractive machining processes, which can lead to cracking and/or other damage. In the illustrated embodiment, the ledge 134 has a solid top surface. Though, in other embodiments, the ledge 134 may comprise a hole through a thickness of the ledge 134 in order to allow for plasma species or the like to flow through the ledge 134 from components above the ledge 134.

Referring now to FIG. 1C, a cross-sectional illustration of a gas delivery manifold 120 is shown, in accordance with an additional embodiment. The gas delivery manifold 120 in FIG. 1C is similar to the gas delivery manifold 120 in FIG. 1B, with the addition of showing an entire width of the base 131, the overlying central column 133, and the ledge 134. As shown, the first portion 161 of the gas line 122 passes into an interior of the central column 133, and the second portion 162 is directed down at the turn 154. Additionally, the second portion 162 of the gas line 122 may pass through a central opening 163 of the base 131. That is, the central opening 163 may be a hole that passes through a thickness of the base 131. This results in the base 131 being ring shaped or the like. As shown, the plenum 127 may surround a perimeter of the central opening 163.

In an embodiment, the ledge 134 may be supported over the base 131 by support columns 132. The ledge 134 may also comprise an opening 169 that leads into the central column 133. In an embodiment, the central columns 133 may have a tapered region to reduce the diameter of the central column 133 to approximately the diameter of the opening 169.

Referring now to FIG. 1D, a cross-sectional illustration of a gas delivery manifold 120 is shown, in accordance with an additional embodiment. In an embodiment, the gas delivery manifold 120 may be similar to the gas delivery manifold 120 with the exception of the inclusion of an RPS mount 146. In an embodiment, the RPS mount 146 may be provided over the ledge 134. The RPS mount 146 may be used to couple an RPS (not shown) to the gas delivery manifold 120. In the illustrated embodiment, the RPS mount 146 may have a tapered region that feeds to a first tube 164. In an embodiment, the first tube exits an edge of the gas delivery manifold 120. The first tube 164 may be coupled to a plasma isolation valve 145. The plasma isolation valve 145 may be a discrete component that is coupled to the gas delivery manifold. The plasma isolation valve 145 may be used to stop the flow or species from the RPS through the remainder of the gas delivery manifold 120. For example, the plasma isolation valve 145 may be opened during cleaning operations or the like. In an embodiment, the RPS mount 146 may also comprise a second tube 165 that extends from the edge of the gas delivery manifold 120. For example, the second tube 165 may be coupled to an output of the plasma isolation valve 145. The second tube 165 may pass through the ledge 134 to fluidly couple with an interior of the central column 133. The RPS mount 146 may also comprise one or more embedded cooling channels 148.

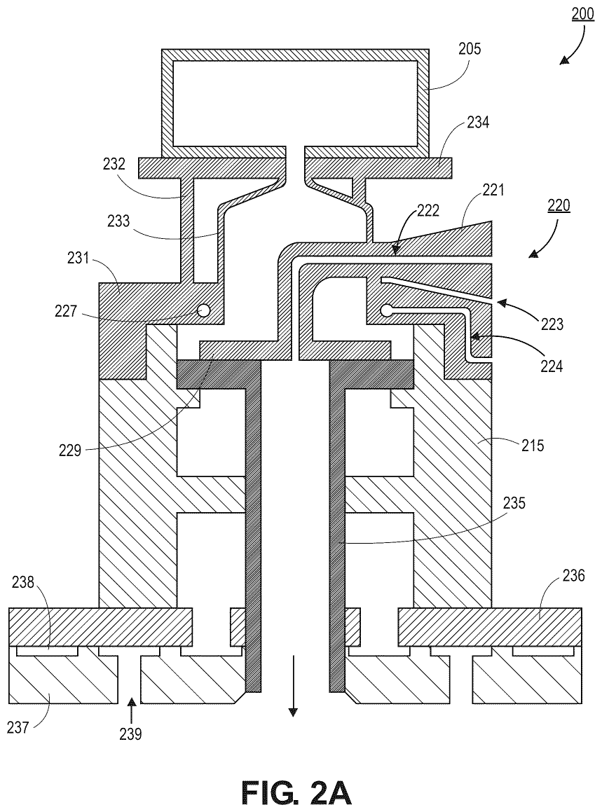

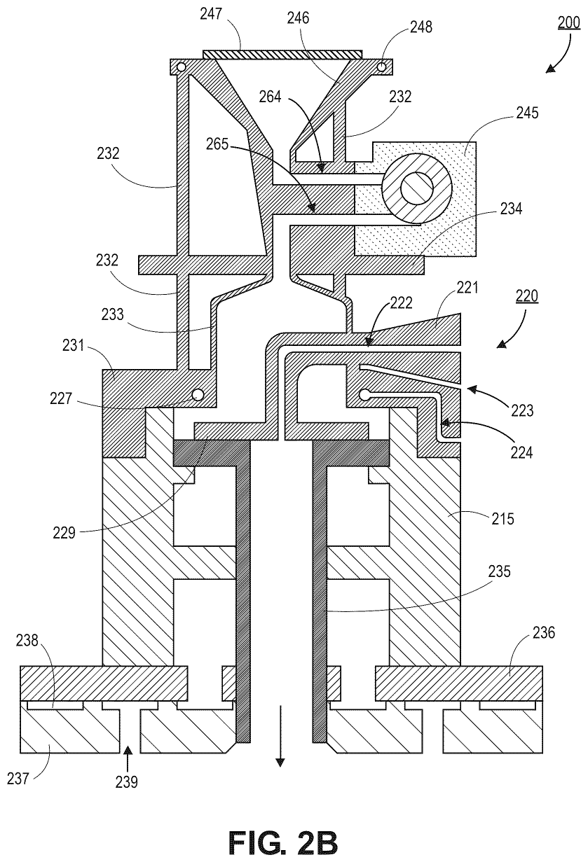

Referring now to FIG. 2A, a cross-sectional illustration of a portion of a plasma processing tool 200 is shown, in accordance with an embodiment. In an embodiment, the plasma processing tool 200 may comprise a gas delivery manifold 220. The gas delivery manifold 220 may be similar to any of the gas delivery manifolds described in greater detail herein. For example, the gas delivery manifold 220 may comprise a base 231 that is separated from a thermal block 221 by a gap 223. In an embodiment, a fluidic channel 224 that is coupled to a plenum 227 may be embedded within the base 231. A gas line 222 may pass through the thermal block 221 and extend into a central column 233. Particularly, it is to be appreciated that the gas line 222 may occupy a small area of the central column 233 (when viewed from a top down perspective). For example, the gas line 222 may occupy up to approximately 10% of the area of the central column 233 (when viewed from a top down perspective). This allows for minimal interference with the flow of radicals through the central column 233. The small area of the gas line 222 can be enabled through the use of the 3D printing process that enables the formation of thin walled segments. In an embodiment, a ledge 234 is supported over the base 231 by a plurality of high aspect ratio support columns 232.

In an embodiment, the tool 200 may further comprise a plasma chamber 205 that is provided above a gas delivery manifold 220. The plasma chamber 205 may be a remote plasma chamber 205 that is supported on a ledge 234 of the gas delivery manifold 220. As shown, the plasma chamber 205 has an opening that feeds into the central column 233 of the gas delivery manifold 220. As such, species from the plasma can pass through the gas delivery manifold 220 and enter a central region of a ceramic shell 215. The ceramic shell 215 may be provided at least partially below the gas delivery manifold 220. The ceramic shell 215 may be supported by a lid 236 of a processing chamber (not shown). In an embodiment, species within the ceramic shell 215 may pass through openings in the lid 236 and into a showerhead 237. The showerhead 237 may comprise gas delivery channels 238 and holes 239 that exit into the processing chamber.

In an embodiment, the gas line 222 may end at the seal plate 229, and the seal plate 229 may interface with a vertical pipe 235 that extends down through the lid 236 and the showerhead 237. In an embodiment, the vertical pipe 235 may also comprise a ceramic material. The combination of the vertical pipe 235 and the gas line 222 of the gas delivery manifold 220 keep gas flowing to the chamber segregated from species flowing through the central column 233 of the gas delivery manifold 220 and the ceramic shell 215. As such, any reaction between the species and the gas will only occur within the chamber below the showerhead 237.

In an embodiment, the gas delivery manifold 220 may be held at RF ground. At the same time, the chamber lid 236 may be held at an RF voltage (i.e., the chamber lid 236 may be considered RF hot). As such, there is a potential for striking a plasma within the gas delivery manifold 220 and/or between the gas delivery manifold 220 and the chamber lid 236. In an embodiment, the ceramic shell 215 between the gas delivery manifold 220 and the chamber lid 236 may mitigate the chance of striking a plasma before the species enter the chamber. In an embodiment, the ceramic shell 215 and/or the vertical pipe 235 may comprise a ceramic material such as alumina or the like. In an embodiment, one or both of the ceramic shell 215 or the vertical pipe 235 may be formed with a 3D printing process.

Embodiments disclosed herein enable excellent thermal control throughout the processing tool 200. For example, the thermal block 221 and the gas line 222 may be maintained at a first temperature, and the base 231 may be maintained at a second temperature that is significantly lower than the first temperature. For example, the base 231 may have a temperature that is approximately 200° C. lower than a temperature of the thermal block 221 and/or the gas line 222. In some embodiments, the thermal block 221 and/or the gas line 222 may have a temperature of approximately 300° C. or higher, while the base 231 has a temperature up to approximately 50° C. Additionally, the ceramic shell 215 may be provide thermal isolation from a heated plate of the chamber lid 236. For example, the heated plate of the chamber lid may be maintained at approximately 150° C. or higher.

Referring now to FIG. 2B, a cross-sectional illustration of a portion of a plasma processing tool 200 is shown, in accordance with an additional embodiment. In an embodiment, the plasma processing tool 200 in FIG. 2B may be similar to the plasma processing tool 200 in FIG. 2A, with the exception of the inclusion of a plasma isolation valve 245. In an embodiment, the plasma isolation valve 245 may be provided between an RPS mount 246 and a remaining portion of the gas delivery manifold 220. The plasma isolation valve 245 may be a discrete component that is coupled to the gas delivery manifold 220. In an embodiment, a first tube 264 from the RPS mount 246 may feed into the plasma isolation valve 245, and a second tube 265 may be coupled to an output of the plasma isolation valve 245. In an embodiment, the RPS mount 246 may include one or more embedded cooling channels 248. In the illustrated embodiment, a lid 247 is provided over the top of the RPS mount 246. Though, it is to be appreciated that any suitable RPS device may be coupled to the RPS mount 246.

In an embodiment, plasma isolation valve 245 allows for species from the plasma of the RPS to be provided into the chamber of the plasma processing tool 200 at desired times (e.g., during a chamber clean). In an embodiment, at least a portion of the RPS mount 246 may be part of the monolithic gas delivery manifold 220, as described in greater detail herein. As shown, the additional height of the complete gas delivery manifold 220 may further be supported by additional support columns 232 between the ledge 234 and the RPS mount 246. The ledge 234 may also at least partially support the plasma isolation valve 245 in some embodiments.

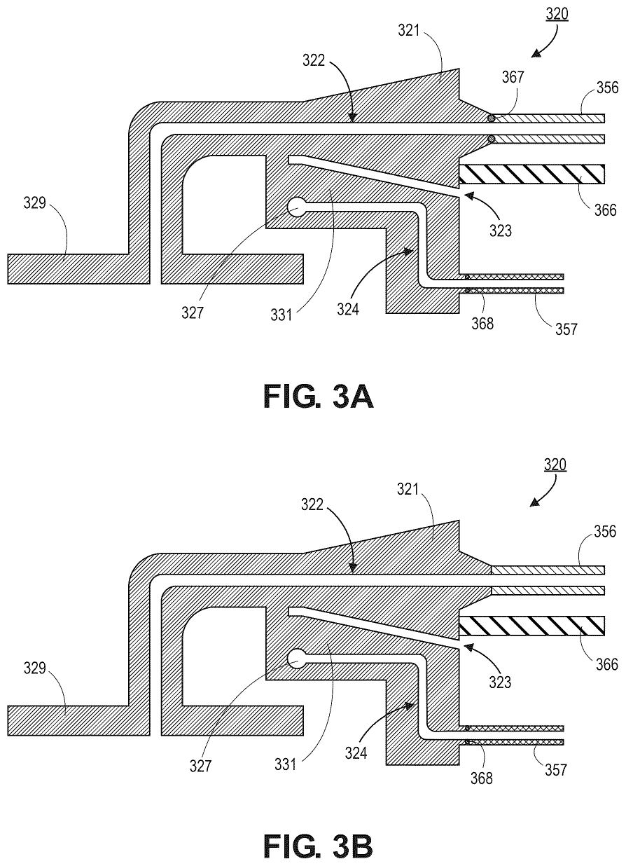

Referring now to FIGS. 3A and 3B, cross-sectional illustrations of portions of gas distribution manifolds are shown, in accordance with additional embodiments. Particularly, FIGS. 3A and 3B illustrate coupling solutions that may be used to connect gas lines and cooling fluid lines to the gas delivery manifold. Due to the high temperature of the thermal block, many O-ring or sealing solutions are not able to be used.

Referring now to FIG. 3A, a cross-sectional illustration of a portion of a gas distribution assembly 320 is shown, in accordance with an embodiment. In an embodiment, the gas distribution assembly 320 may be similar to any of the gas distribution assemblies described in greater detail herein. For example, the gas distribution assembly 320 may comprise a thermal block 321 with an embedded gas line 322. An end of the gas line 322 may pass through a seal plate 329. The gas distribution assembly 320 may also comprise a base 331 that is spaced away from the thermal block 321 by an air gap 323. In an embodiment, a fluidic channel 324 may pass through the base 331 to connect to a plenum 327.

In an embodiment, the gas line 322 may be coupled to a gas input line 356. In the illustrated embodiment, an O-ring 367 is provided between the gas line 322 and the gas input line 356. In order to accommodate the high temperature of the thermal block 321, the O-ring 367 may comprise a metallic coating, such as nickel, silver, tin, or the like. As shown, a power cable 366 may also be coupled to the thermal block 321. The power cable 366 may provide electrical power to the thermal block 321 in order to heat the thermal block 321 to a desired temperature. In an embodiment, a fluidic input line 357 may be coupled to the fluidic channel 324 in the base 331. The fluidic input line 357 may also be coupled to the fluidic channel 324 with an O-ring 368 or the like. Since the fluidic input line 357 is thermally separated from the thermal block 321 by the air gap 323, the temperature requirements of the O-ring 368 are less restrictive.

Referring now to FIG. 3B, a cross-sectional illustration of a portion of a gas distribution manifold 320 is shown, in accordance with an additional embodiment. In an embodiment, the gas distribution manifold 320 in FIG. 3B may be similar to the gas distribution manifold 320 in FIG. 3A, with the exception of the coupling between the gas input line 356 and the gas line 322. For example, some metal coated O-ring materials may not be compatible with the precursor gas that is to be flown into the gas line 322. Accordingly, an alternative seal solution may be needed. As shown in FIG. 3B, the gas input line 356 is directly contacting the gas distribution manifold 320. For example, a welding or brazing process may be used to connect the gas input line 356 to the gas distribution manifold 320. For example, friction stir welding may be used to weld stainless steel of the gas input line 356 to aluminum of the gas distribution manifold 320.

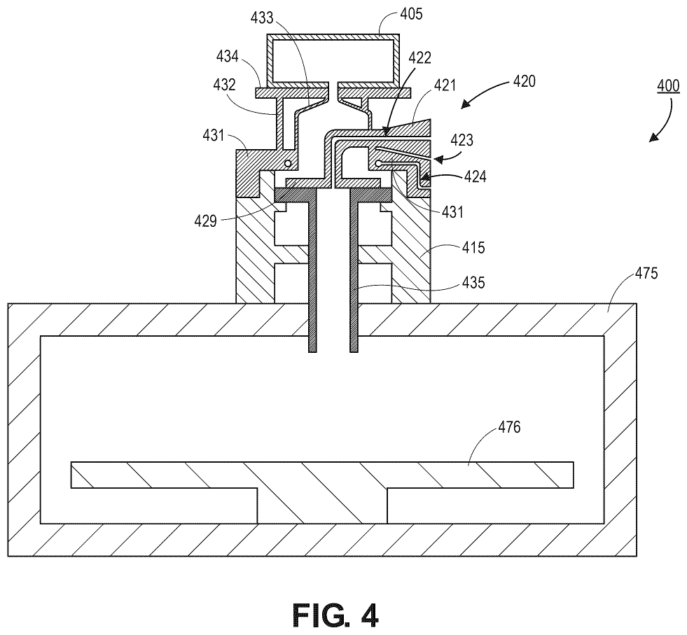

Referring now to FIG. 4, a cross-sectional illustration of a plasma processing tool 400 is shown, in accordance with an embodiment. In an embodiment, the plasma processing tool 400 may comprise a gas distribution manifold 420. In an embodiment, the gas distribution manifold 420 may be similar to any of the gas distribution manifolds described in greater detail herein. For example, the gas distribution manifold 420 may comprise a base 431 with a fluidic channel 424 and a thermal block 421 that is spaced away from the base 431 by an air gap 423. In an embodiment, the gas distribution manifold 420 may further comprise a central column 433 and an overlying ledge 434 that is supported by support columns 432. In an embodiment, an RPS chamber 405 may be provided over the ledge 434.

In an embodiment, a ceramic shell 415 with an interior vertical pipe 435 may be provided below the gas distribution manifold 420. The ceramic shell 415 may provide a path for species from the RPS chamber 405 to pass into the chamber 475. For example, the lid of the chamber 475 may have passages (not shown) to allow the species to pass into an interior of the chamber 475. The vertical pipe 435 may couple to a seal plate 429 of the gas distribution manifold 420. The vertical pipe 435 may pass through the lid of the chamber 475 in order to allow a precursor gas that is flown through the gas line 422 to enter the chamber 475.

In an embodiment, the chamber 475 may be a chamber for implementing any suitable plasma processing operation, such as etching, deposition, plasma treatment, and/or the like. In an embodiment, the chamber 475 may comprise a pedestal with a chuck 476 for supporting a substrate (not shown), such as a semiconductor wafer or the like.

In an embodiment, the gas distribution assembly 420 may be configured to provide a high temperature path that allows for a precursor gas to be delivered to the chamber 475 without condensing. For example, gas within the gas line 422 and the vertical pipe 435 may remain at a temperature of approximately 200° C. or higher, approximately 250° C. or higher, or approximately 300° C. or higher.

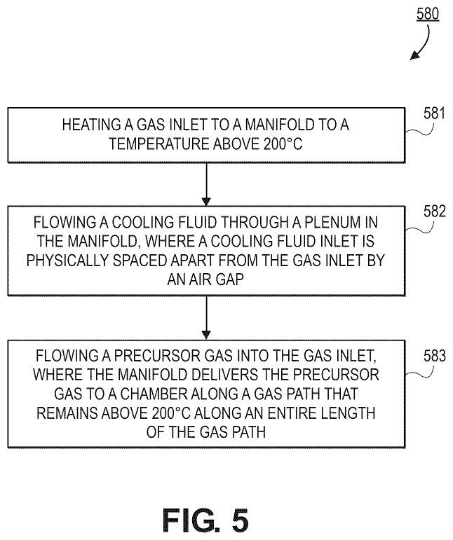

Referring now to FIG. 5, a flow diagram of a process 580 for delivering a precursor gas to a chamber without allowing the precursor gas to condense before reaching the chamber is shown, in accordance with an embodiment. In an embodiment, the process 580 may begin with operation 581, which comprises heating a gas inlet to a manifold to a temperature of approximately 200° C. or higher, approximately 250° C. or higher, or approximately 300° C. or higher. In an embodiment, the manifold may comprise a metallic material that is a monolithic structure. For example, the manifold may be fabricated with a 3D printing process. In an embodiment, the manifold may be similar to any of the gas delivery manifolds described in greater detail herein.

In an embodiment, the process 580 may continue with operation 582, which comprises flowing a cooling fluid through a plenum in the manifold. In an embodiment, a cooling fluid inlet is physically spaced apart from the gas inlet by an air gap. The presence of the air gap allows for the generation of a thermal chock that minimizes heat transfer from the hot thermal block surrounding the gas inlet.

In an embodiment, the process 580 may continue with operation 583, which comprises flowing a precursor gas into the gas inlet. In an embodiment, the manifold delivers the precursor gas to a chamber along a gas path that remains at or above approximately 200° C. along an entire length of the gas path. In some embodiments, the precursor gas comprises ZrCl gas. The ZrCl gas may be used for a PE titanium deposition process within the chamber.

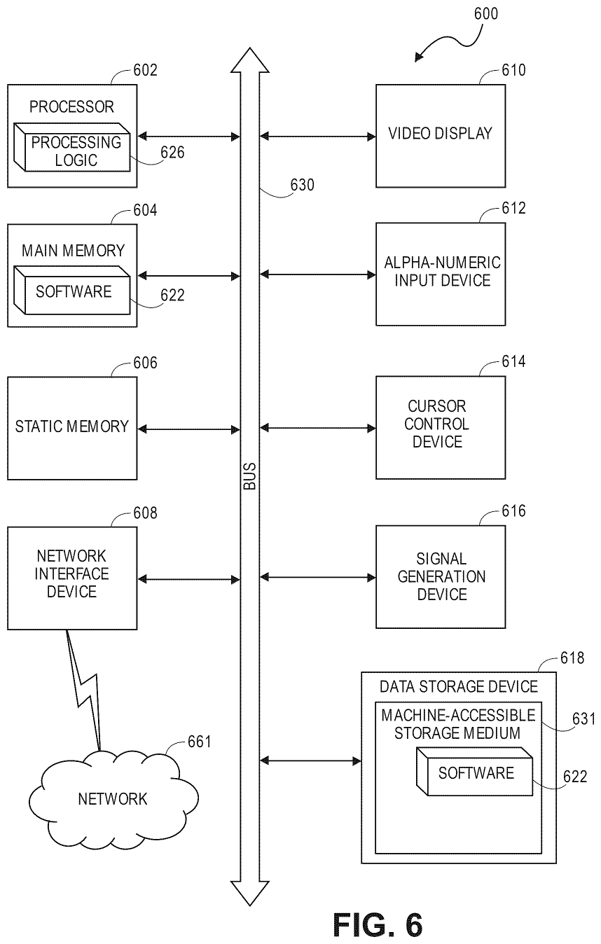

Referring now to FIG. 6, a block diagram of an exemplary computer system 600 of a processing tool is illustrated in accordance with an embodiment. In an embodiment, computer system 600 is coupled to and controls processing in a plasma processing chamber with a monolithic 3D printed gas delivery manifold that comprises a thermal block for maintaining a high temperature for a gas delivery line within the gas delivery manifold.

Computer system 600 may be connected (e.g., networked) to other machines in a Local Area Network (LAN), an intranet, an extranet, or the Internet. Computer system 600 may operate in the capacity of a server or a client machine in a client-server network environment, or as a peer machine in a peer-to-peer (or distributed) network environment. Computer system 600 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 600, the term “machine” shall also be taken to include any collection of machines (e.g., computers) that individually or jointly execute a set (or multiple sets) of instructions to perform any one or more of the methodologies described herein.

Computer system 600 may include a computer program product, or software 622, having a non-transitory machine-readable medium having stored thereon instructions, which may be used to program computer system 600 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 600 includes a system processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

System processor 602 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 602 may also be one or more special-purpose processing devices such as an application specific integrated circuit (ASIC), a field programmable gate array (FPGA), a digital signal system processor (DSP), network system processor, or the like. System processor 602 is configured to execute the processing logic 626 for performing the operations described herein.

The computer system 600 may further include a system network interface device 608 for communicating with other devices or machines. The computer system 600 may also include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium 631 (or more specifically a computer-readable storage medium) on which is stored one or more sets of instructions (e.g., software 622) embodying any one or more of the methodologies or functions described herein. The software 622 may also reside, completely or at least partially, within the main memory 604 and/or within the system processor 602 during execution thereof by the computer system 600, the main memory 604 and the system processor 602 also constituting machine-readable storage media. The software 622 may further be transmitted or received over a network 661 via the system network interface device 608. In an embodiment, the network interface device 608 may operate using microwave coupling, optical coupling, acoustic coupling, or inductive coupling.

While the machine-accessible storage medium 631 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

Thus, embodiments of the present disclosure include systems and methods for delivering a precursor gas to a plasma processing chamber without condensing the precursor gas through the use of a monolithic 3D printed gas delivery manifold that comprises a thermal block for maintaining a high temperature for a gas delivery line within the gas delivery manifold.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

What is claimed is:

1. An apparatus, comprising:
a thermal block with a gas inlet;
a gas line fluidly coupled to the gas inlet of the thermal block; and
a base that is coupled to the thermal block, wherein the base comprises an embedded channel coupled to a fluid inlet, and wherein an air gap is provided between at least a portion of the thermal block and a portion of the base.

2. The apparatus of claim 1, wherein the base and the thermal block are part of a monolithic structure.

3. The apparatus of claim 1, wherein the channel comprises a horizontal portion and a vertical portion.

4. The apparatus of claim 3, wherein the channel further comprises a plenum fluidly coupled to the vertical portion, wherein the plenum is a ring.

5. The apparatus of claim 1, wherein the gas line comprises a turn that is approximately ninety degrees.

6. The apparatus of claim 1, wherein the thermal block and the base comprise aluminum.

7. The apparatus of claim 1, wherein the base is a ring, and wherein the gas line passes at least partially through a center of the ring.

8. The apparatus of claim 1, further comprising:
a remote plasma source (RPS) mount coupled to the base.

9. The apparatus of claim 8, wherein the RPS mount is coupled to the base by a plurality of supports.

10. The apparatus of claim 9, wherein the RPS mount, the plurality of supports, and the base are a monolithic structure.

11. An apparatus, comprising:
a monolithic gas delivery manifold, wherein the monolithic gas delivery manifold comprises:
a gas line, wherein a gas input to the gas line is at a surface of a thermal block;
a base, wherein the base comprises a fluidic channel, and wherein an air gap is provided between at least a portion of the thermal block and a portion of the base;
a remote plasma source (RPS) mount above the base, wherein the RPS mount is coupled to the base by a plurality of support columns;
a plasma isolation valve between the RPS source mount and the base;
a vertical pipe fluidically coupled to the gas line; and
a chamber, wherein the vertical pipe is fluidically coupled to an interior of the chamber.

12. The apparatus of claim 11, wherein the air gap is non-orthogonal with respect to an edge of the monolithic gas delivery manifold.

13. The apparatus of claim 11, wherein the fluidic channel comprises a horizontal portion and a vertical portion.

14. The apparatus of claim 11, wherein the vertical pipe comprises a ceramic material.

15. The apparatus of claim 11, further comprising:
a shell around the vertical pipe, wherein the shell comprises a ceramic material; and
a plate, wherein the shell is between the base of the monolithic gas delivery manifold and the plate, and wherein thermal block is configured to be held at a first temperature, the base is configured to be held at a second temperature that is at least 200° C. lower than the first temperature, and the plate is configured to be held at a third temperature that is between the first temperature and the second temperature.

16. The apparatus of claim 11, further comprising:
a showerhead, wherein the vertical pipe passes at least partially through the showerhead.

17. The apparatus of claim 11, wherein the gas line comprises an approximately ninety degree turn.

18. An apparatus, comprising:
a chamber;
a gas delivery manifold fluidly coupled to the chamber, wherein the gas delivery manifold comprises a gas line that is configured to be heated, wherein the gas line comprises a vertical portion and a horizontal portion; and
a remote plasma source (RPS) coupled to the gas delivery manifold, wherein the RPS is fluidly coupled to an interior of the chamber by a path that passes through the gas delivery manifold.

19. The apparatus of claim 18, wherein the gas delivery manifold comprises a fluidic channel, wherein the fluidic channel comprises a plenum ring.

20. The apparatus of claim 18, further comprising:
a plasma isolation valve between the RPS and the chamber.
